(19) United States
(12) Patent Application Publication
(10) Pub. No.: US 2003/0226251 A1
(43) Pub. Date: Dec. 11, 2003

(54) Fitting system and method of fitting substrates with components

(76) Inventors: Mohammad Mehdianpour, Muenchen (DE); Harald Stanzl, Muenchen (DE)

Correspondence Address: HARNESS, DICKEY & PIERCE, P.L.C., P.O.BOX 8910, RESTON, VA, 20195, US

(21) Appl. No.: 10/348,751

(22) Filed: Jan. 23, 2003

(30) Foreign Application Priority Data
Jun. 7, 2002 (DE) 10225430.3

(51) Int. Cl. B23P 19/00; H05K 3/30

(52) U.S. Cl. 29/739; 29/742; 29/832

(57) ABSTRACT

A fitting system and a method of fitting substrates with components includes, along a conveyor line, loading apparatuses provided in a conveying direction. Each of the loading apparatuses include at least two holding regions arranged one above another, so that substrates delivered along the conveyor line can be transferred to the upper holding region or the lower holding region. In this case, it is possible to feed substrates to fitting areas and at the same time to move substrates past the fitting areas. This achieves a very high performance per unit area of the fitting system. Furthermore, great flexibility is possible in the selected processing of the substrates.

The present application hereby claims priority under 35 U.S.C. §119 on German patent application number DE 10225430.3 filed Jun. 7, 2002, the entire contents of which are hereby incorporated herein by reference.

1. Field of the Invention

The invention generally relates to a fitting system and a method of fitting substrates with components. Preferably, it relates to one in which the substrates can be fed on a substantially linear conveyor line. Further, it preferably includes at least one feed device for feeding components and also at least one fitting area having a handling apparatus for fitting the components fed in to the substrates being arranged at the side of the conveyor line.

2. Background of the Invention

Fitting systems are nowadays widespread for fitting substrates with components, in particular with So) components. The substrates are conventionally fed in on a conveyor line. Arranged along the conveyor line are fitting areas. Once a substrate reaches a fitting area, its position is determined relative to a handling apparatus, which is arranged in the fitting area to fit the components to these substrates. The components are then fitted to the substrate by means of the handling apparatus.

In the case of conventional fitting systems, faults can occur in a fitting area during fitting, slowing the fitting in the fitting area or bringing it entirely to a standstill. In this way, the entire conveyor line is slowed down or stopped. This results in severe impairment to the performance in conventional fitting systems.

### SUMMARY OF THE INVENTION

An embodiment of the invention is therefore based on an object of specifying a fitting system and a method of fitting substrates with components in which the fitting performance is increased and which is not susceptible to faults.

By use of a loading apparatus having at least two holding regions arranged one above another to hold and discharge substrates, the fitting system according to an embodiment of the invention permits flexible delivery of substrates to and from the fitting areas and flexible forwarding of substrates along the conveyor line of the fitting system past the fitting areas.

The substrates fed along the conveyor line can be transferred into each of the holding regions provided at the loading apparatus. The loading apparatus can transfer the substrates both from the upper holding region and from the lower holding region either to a fitting area, where they can be fitted, or to another subarea of the conveyor line, from where they can be conveyed onward to another fitting system without being processed.

This makes it possible, at the same time as substrates are transferred to a fitting area, to transfer other substrates, not to be fitted within a fitting area of this fitting system, to another subarea of the conveyor line. The substrates transferred in this way can be fitted at a free fitting area in another fitting system.

For example, the printed circuit boards can be transferred from the conveyor line into the upper holding region of the loading apparatus. From this point, for the case in which the incoming substrates are not be processed in this fitting system, there is the possibility of lowering the loading apparatus by use of a vertical drive and, from the lowered position, of transferring said substrates to a further subarea of the conveyor line for onward transport to another fitting system. On the other hand, it is also possible to leave the loading apparatus in its original vertical position and to transfer the incoming substrates to the fitting areas.

As a result of the multi-story arrangement of the loading apparatuses, it is possible, at the same time as the transfer of substrates to fitting areas, to move other substrates within the same fitting system past the fitting areas and to transfer them to the conveyor line for onward transport to another fitting system.

Furthermore, even after the substrates have been fitted by use of the loading apparatus, these fitted substrates can be transferred to different conveyor lines. For example, it is possible to transfer the fitted substrates to a bypass conveyor line, from where they can be fed directly to further processing, for example to a soldering oven. On the other hand, the already fitted substrates can also be transferred to a fitting conveyor line, which conveys them to another fitting system where they can be processed further. It is also possible for the conveyor lines themselves to be constructed with two or more stories and consequently to have two or more conveying regions, for example a fitting line and a bypass line for the substrates, located one above another. This allows still more flexible operation of the fitting system.

The incoming substrates do not initially have to be put sequentially into the plurality of holding regions of the loading apparatus, but can be transferred simultaneously from the different conveying regions of the conveyor line, lying one above another, into the holding regions arranged one above another in the loading apparatus. Likewise, following the fitting of the substrates, it is possible by means of the loading apparatus in turn to transfer a plurality of substrates simultaneously from the holding regions of the loading apparatus, arranged one above another, to the conveyor regions of the conveyor line, located one above an another. For this purpose, the distance between the holding regions of the loading apparatus in the vertical direction is preferably substantially equal to the vertical distance between the conveyor regions of the conveyor line located one above another.

If the fitting areas are arranged at the side of the conveyor line, the conveyor line can be interrupted in the conveying direction by the fitting areas. The loading apparatus in this case can be moved within the interruption in the conveying direction, in order to permit the interruption to be bridged. In this case, the loading apparatus can be moved within the interruption to a position at which the holding regions of the loading apparatus are aligned with corresponding holding regions of the fitting areas, so that substrates to be fitted can be transferred to the fitting areas or fitted substrates can be transferred from the fitting areas to the loading apparatus. Furthermore, pairs of substrate carriers can be provided, which are assigned to the fitting areas of at least one of the two sides along the conveyor line. Each pair of substrate carriers can have two substrate carriers, which in each case can be moved in a movement direction at an angle to the conveying direction.

As a result of the substrate carriers that can be moved transversely with respect to the conveying direction, flexible, fast, fault-insusceptible handling of the substrates within the fitting system is possible. In this case, the substrates fed in along the conveying line are transferred to the substrate carriers by use of the loading apparatus and moved by the latter into the fitting areas, remaining on the substrate carrier within the fitting area during fitting. After fitting has been carried out, the substrates are moved by means of the substrate carriers, in the direction of movement of the substrate carriers, to the conveying line, where they can be transferred to a loading apparatus. From the loading apparatus, the fitted substrates are moved in the conveying direction to the conveyor line and transferred to the latter for onward transport.

In order to allow even more flexible operation of the fitting system, the movement regions of the substrate carriers of each pair of substrate carriers can overlap in the region of the conveyor line, so that by means of each substrate carrier, any desired position in relation to the conveying line can be assumed.

By use of the alternatives provided in the method according to an embodiment of the invention of fitting, substrates, during the transfer of substrates from the conveyor line to the loading apparatus, from the loading apparatus to the fitting areas and, respectively, from the fitting area to the loading apparatus and from the loading apparatus to the conveyor line, a large number of different operating modes of a fitting system according to an embodiment of the invention is possible.

For example, in an upper holding region of the loading apparatus, substrates can be fed from the conveyor line to the fitting areas of a fitting system, while at the same time, by means of the same loading apparatus, substrates can be transferred past the fitting areas to a part of the conveyor line which leads onward.

In addition, when substrates are accepted by the fitting areas, by assessing information as to whether the substrates are to be processed further in another fitting system, appropriately suitable onward transport is ensured, in which the fitted substrates are transferred from the loading apparatus into an appropriate conveying region of the conveyor line. Depending on the region of the conveyor line in which the fitted substrates are transferred, the latter can be moved directly past the fitting areas of the next fitting system or processed further in the fitting areas of the next fitting system.

For this purpose, the conveying line can be subdivided into a fitting line and a bypass line, which are arranged one above another. On the fitting line, substrates are preferably fed to the fitting areas or led away from the latter. On the bypass line, substrates are preferably moved past the fitting areas of a fitting system.

### BRIEF DESCRIPTION OF THE DRAWINGS

The invention will be explained in more detail with reference to the drawings, in which:

FIG. 1 shows a schematic side section of a preferred embodiment of the invention,

FIG. 2 shows a schematic section in plan view of a further preferred embodiment of the invention,

FIGS. 3 and 4 show a schematic side section and a schematic section in plan view of a further preferred embodiment of the invention and

FIGS. 5a to 5g show schematic illustrations of method steps belonging to a method of an embodiment of the invention.

### DETAILED DESCRIPTION OF THE PREFERRED EMBODIMENTS

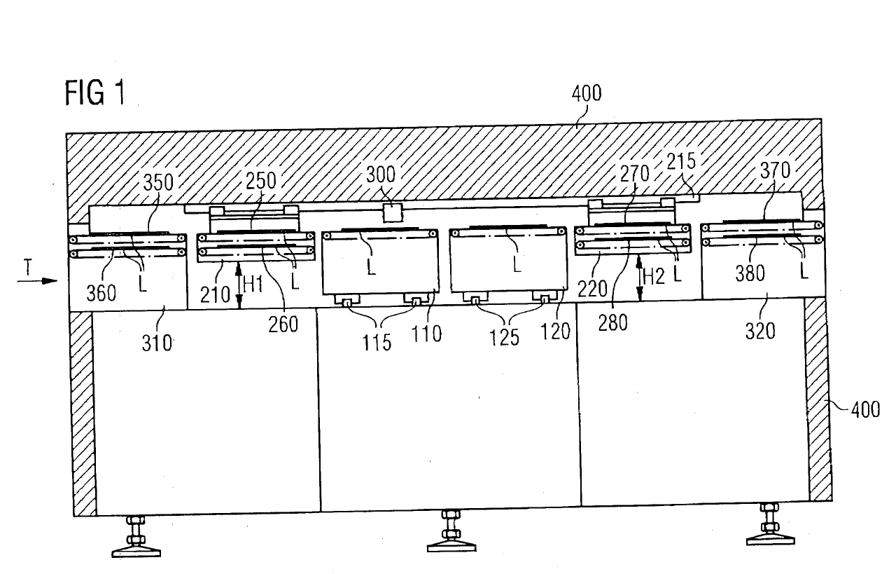

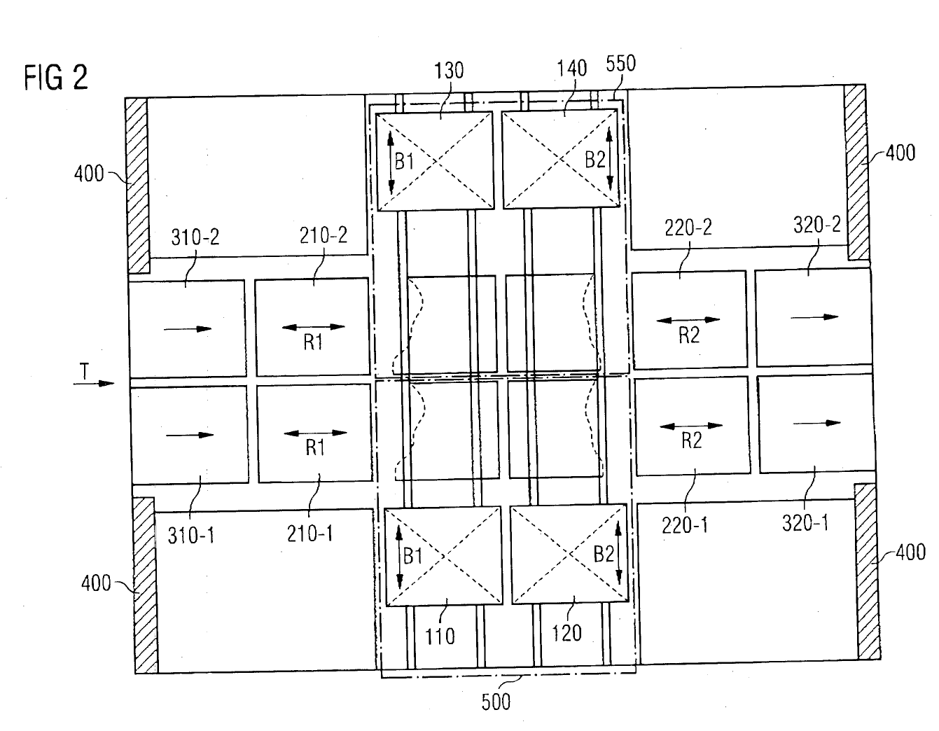

FIGS. 1 and 2 reveal a preferred embodiment of the system according to an embodiment of the invention. In this case, a chassis 400 has a substantially rectangular outline. Along the longitudinal extent of the chassis 400, a conveyor line 310, 320 runs along the conveying direction T. The conveyor line 310, 320 is built up in a plurality of stories, for example two stories, and has upper conveying regions 350, 370 and lower conveying regions 360, 380. Along the conveyor line 310, 320, substrates, preferably printed circuit boards L, are fed to the fitting system and led away from the latter. Printed circuit boards L are preferably fed in at the input station 310, which has one or more acceptance positions 350, 360.

In order to be able to convey the printed circuit boards L, the input station 310 is, for example, provided with conveyor belts, on which the substrates L can be conveyed lying down. However, it is also possible to provide grippers which grip the substrates L, preferably in their lateral regions, and move them onward. Arranged to follow the input station 310 in the conveying direction T is a loading apparatus 210, which can be moved in the vertical direction H1 and in the conveying direction T. From the input station 310, substrates L can be transferred to the loading apparatus 210. The loading apparatus 210 can, for example, have conveyor belts and/or grippers for conveying the substrates L, in a way similar to the input station 310.

The loading apparatus 210 is displaceably mounted on a rod-like guide device 215, which is designed to extend over the conveyor line on the chassis 400 and along the conveying direction. A measuring system 300, in particular a camera, can also be arranged on the rod-like guide device 215 and can be moveable along the conveying direction T. Downstream of the loading apparatus 210, transversely or at an angle with respect to the conveying direction T, two guide devices 115 and 125 are arranged. The two guide devices 115, 125 are each provided with a pair of substrate carriers 110, 120, 130, 140. Each pair of substrate carriers has two substrate carriers 110 and 130 and, respectively, 120 and 140. The substrate carriers can in each case be moved on the guide device 115 or 125 at an angle with respect to the conveying direction T. In this case, each substrate carrier 110, 120, 130 and 140 can be moved between the conveyor line 310, 320 and the fitting areas (not shown in FIG. 1), in order for substrates L, which are allocated to the substrate carriers by means of the loading apparatus 210, to be moved to the fitting areas or to be moved away from the fitting areas again into the alignment of the conveyor line 310, 320.

Optionally arranged following the substrate carriers, downstream in the conveying direction T, is an unloading apparatus 220, which can be moved in a vertical direction H2 and in the conveying direction T and has at least two holding regions 250, 260 arranged one above another for substrates L. The unloading apparatus 220 is constructed in a manner analogous to the loading apparatus 210 and is likewise guided on the rod-like guide device 215 belonging to the chassis 400. The unloading apparatus 220 can likewise be moved from its rest position into the entire central region between the input station 310, the substrate carriers 110, 120, 130 and 140 and an output station 320, along the conveying direction T. The output station 320 is constructed in a manner analogous to the input station 310.

FIG. 2 reveals a further preferred embodiment of the fitting system according to an embodiment of the invention. The difference from the fitting system according to the preferred embodiment according to FIG. 1 is that two conveyor lines 310-1, 310-2, 320-1, 320-2 arranged beside one another, corresponding loading apparatuses 210-1, 210-2 arranged beside one another and unloading apparatuses 220-1, 220-2 arranged beside one another are provided. Otherwise, the embodiment according to FIG. 2 corresponds to the embodiment according to FIG. 1. The advantage in the further embodiment of the invention, according to FIG. 2, is that a higher throughput of substrates through the fitting system is possible by means of the two conveyor lines arranged in parallel.

Using a fitting system according to the invention, inter alia the following possible passages for substrates L through the fitting system according to an embodiment of the invention can be implemented.

A substrate L delivered along the conveyor line can arrive either in the upper conveying region 350 (fitting line) or in the lower conveying region 360 (bypass line) of the input station 310. From this position, the substrate can be transferred by means of the loading apparatus 210 into the upper holding region 250 or into the lower holding region 260 of the loading apparatus 210. For this purpose, it may be necessary for the loading apparatus 210 to be moved in the vertical direction H1 before the transfer into the appropriate holding region 250, 260 can take place. It is also possible, at the same time, to transfer at most two or more substrates L from the input station 310 to the loading apparatus 210, corresponding to the corresponding number of holding regions of the loading apparatus and of conveying regions of the conveyor line.

From the loading apparatus 210, a substrate L can be transferred either from the upper holding region 250 or from the lower holding region 260 to a substrate carrier 110, 120, 130, 140, from which it can be moved to a fitting area 500, 550 in order to be processed there.

However, it is also possible to transfer substrates L both from the upper holding region 250 and from the lower holding region 260 of the loading apparatus 210 directly to the output station 320 in its upper conveying region 370 (fitting line) or its lower conveying region 380 (bypass line). For this purpose, the loading apparatus 210 can be moved over the two guide devices 115 and 125 as far as the output station 320, in order to transfer the substrates L there. In this case, parallel transfer of two or more substrates is also possible, depending on the number of holding regions and conveying regions.

Should completely processed substrates, which have been processed within a fitting area 550 or 500 in the fitting system according to an embodiment of the invention, be transferred to the conveyor line for onward transport, then after the substrate carrier has been moved into the central region in alignment with the conveyor line, said substrates can be transferred either to the loading apparatus 210 or to an unloading apparatus 220 constructed in a manner analogous to the loading apparatus and having corresponding holding regions 270 and 280. The loading apparatus 210 or the unloading apparatus 220 can transfer the substrates L, as described above, to the output station 320 for onward transport.

In order to transfer substrates between the loading apparatuses 210 and 220 and the substrate carriers 110, 120, 130, 140, the substrate carriers in each case have to be moved in the direction B1 or the direction B2 into a region aligned with the conveyor line, so that the printed circuit boards can be transferred from the loading apparatus 210 or the unloading apparatus 220 to the substrate carriers 110, 120, 130 and 140. The same is true of the transfer of substrates L from the substrate carriers 110, 120, 130 and 140 to the loading apparatus 210 or the unloading apparatus 220.

In order to transfer substrates L directly beyond the region of the guide devices 115 and 125, from the input station 310 to the output station 320, in each case the loading apparatus 210 and the unloading apparatus 220 can be moved into the center of the region above the two guide devices 115 and 125. If both the unloading apparatus 220 and the loading apparatus 210 have in each case been moved as far as the center above the two guide devices 115 and 125, substrates L can be transferred directly from the holding regions 250, 260 of the loading apparatus 210 to the holding regions 270, 280 of the unloading apparatus 220. However, it is also possible to bridge the distance between the loading apparatus 210 and the unloading apparatus 220 merely by moving one of the two apparatuses 210, 220.

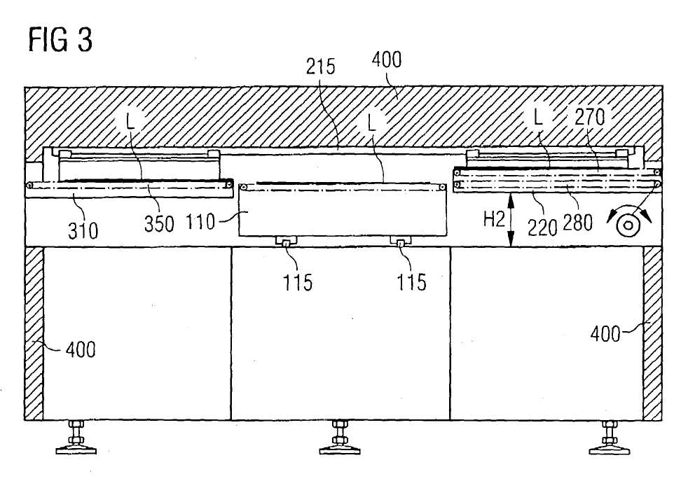

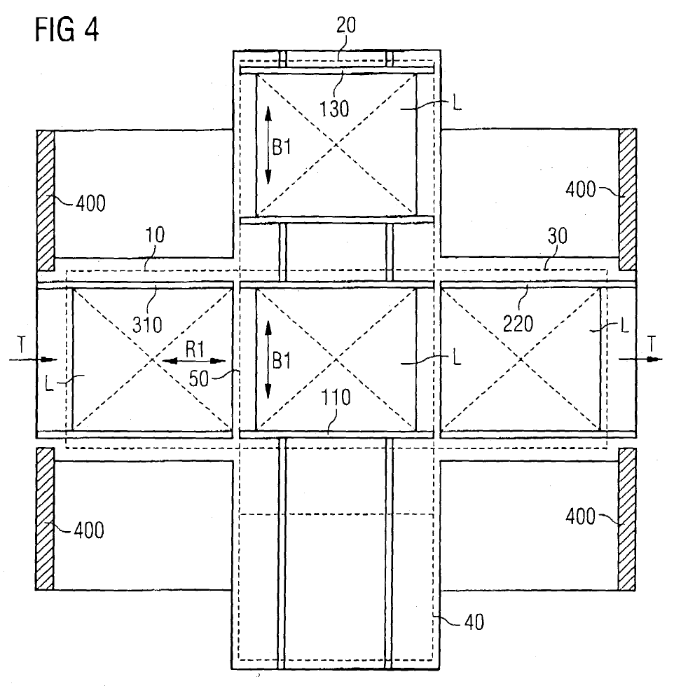

FIGS. 3 and 4 reveal a further preferred embodiment of the system according to the invention. In this case, a chassis 400 has a substantially rectangular outline. Along the longitudinal extent of the chassis 400, a conveyor line runs along the conveying direction T. Viewed in the conveying direction, the conveyor line has an input station 310 upstream to feed printed circuit boards L in.

In the further embodiment, the input station 310 is of single-story design and has an acceptance position for printed circuit boards L. In order to be able to convey the printed circuit boards L, the input station 310 is provided, for example, with conveyor belts, on which the substrates L can be conveyed lying down. However, it is also possible to provide grippers which grip the substrates L, preferably in their lateral regions, and move them onward.

In the conveying direction T, following the input station 310, a pair of substrate carriers 110, 130 is provided. The pair of substrate carriers is arranged to be mounted on a guide device 115. The individual substrate carriers 110, 130 can each be moved along the guide device 115 in the direction B1 and at angle to the conveying direction T. In this case, each substrate carrier 110, 130 can be moved between the conveyor line, in particular its input station 310 and the fitting areas 20 and 40 in FIG. 4, in order to move substrates L which have been transferred to the substrate carriers 110, 130 by means of the input station 310 to the fitting areas and/or to move the substrates L from the fitting areas in the conveying direction T into the alignment of the conveyor line again.

Arranged to follow the substrate carriers 110 and 130, downstream in the conveying direction T, is an unloading apparatus 220, which can be moved in a vertical direction H2 and has at least two holding regions 270, 280 for substrates L, arranged one above another. The unloading apparatus 220 can also be constructed such that it can be moved in the conveying direction T, so that it can be moved within the regions 10, 50 and 30 of the system according to the invention in order to be able to accept substrates from the input station 310 and to transfer the substrates downstream in the conveying direction T to the conveyor line for onward transport. For this purpose, the unloading apparatus 220 is, for example, provided with conveyor belts in its holding regions 270 and 280.

According to the further embodiment of the system according to the invention, as can be seen from FIG. 4, it is possible both for a single conveyor line to be arranged in the conveying direction T and also for a plurality of conveyor lines to be arranged parallel to one another in the direction T. Furthermore, as in the preferred embodiment, a second pair of substrate carriers 120, 140 can be provided such that they can be moved transversely with respect to the conveying direction T.

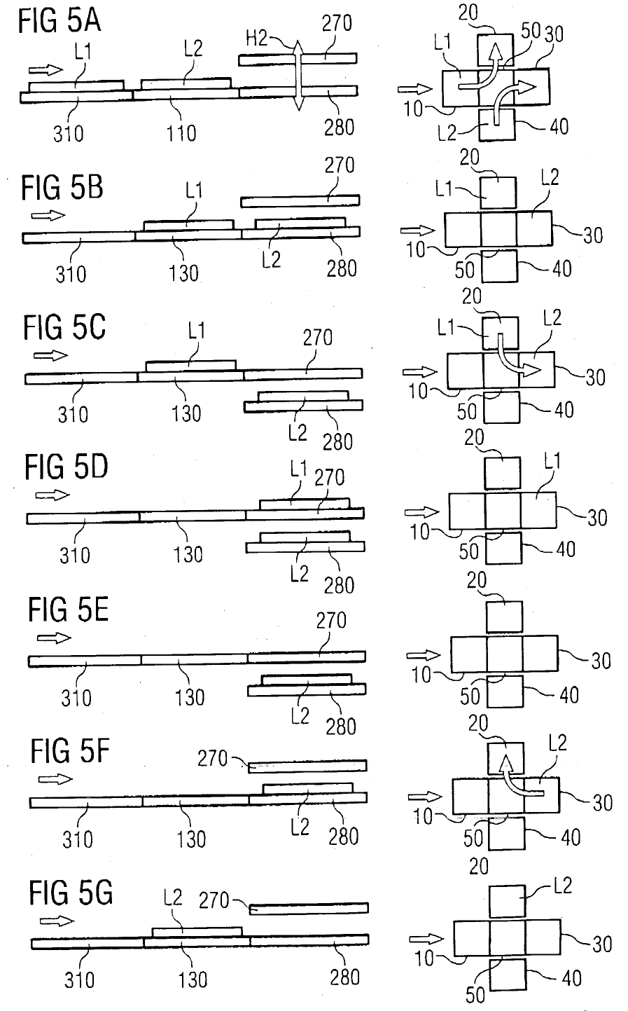

With a fitting system according to the further embodiment of the invention, inter alia the possible passage which can be seen from FIGS. 5a to 5h for substrates L can be implemented by use of the fitting system according to an embodiment of the invention. FIGS. 5a to 5h illustrate the moved elements of the fitting system according to the invention in accordance with the further embodiment, in each case the left-hand part of the figure revealing a schematic side view of the moved elements of the fitting system according to the invention and the right-hand part of the figure revealing a plan view of the various regions 10, 20, 30, 40 and 50 of the fitting system according to the invention, to which regions the substrates L can be moved.

As FIG. 5a reveals, in a first step of the method according to the invention, a first substrate L1 is arranged in the input station 310. A second substrate L2 is located on the substrate carrier 110. The unloading station 220 has been moved upward in the vertical direction H2 into its upper position, so that the lower holding region 280 is aligned horizontally with the conveyor line. As can be seen from the right-hand part of FIG. 5a, the substrate L1 is in the region 10 and the substrate L2 in the region 40, the second fitting area of the fitting system. Furthermore, the desired movement sequences of the substrates L1 and L2 can be seen from the right-hand part of FIG. 5a. Thus, substrate L1 is to be moved into the region 20, that is to say a first fitting area, and substrate L2 is to be moved from the second fitting area 40 into the position 30 from where it can be transferred to the conveyor line.

As can be seen from the further FIGS. 5b to 5g, this is carried out in that, firstly, the substrate L2 is transferred into the lower holding region 280 of the unloading apparatus 220. The first substrate L1 can then be moved into the first fitting area 20 by use of the substrate carrier 130. After the first step, therefore, the first substrate L1 is in the first fitting area 20, and the second substrate L2 is in the unloading apparatus 220, in the lower holding region 280 thereof.

In a third step, first of all the unloading apparatus is moved in the vertical direction H2 from its upper position into its lower position, so that the holding region 270 is aligned horizontally with the conveyor line in the conveying direction T. The substrate L1 can then be transferred to the upper holding region 270 of the unloading apparatus 220 by use of the substrate carrier 130, which has been moved into the region 50 of the fitting system. At the end of the third step, as FIG. 5d reveals, the unloading apparatus 220 is therefore in its lower position in the vertical direction H2, and the first substrate L1 is in the upper holding region 270 of the unloading apparatus 220. The second substrate L2 is in the lower holding region 280. The two substrates are therefore arranged one above another in the region 30 of the fitting system.

In a fourth step, as FIG. 5e reveals, the first substrate L1, which is a completely fitted substrate, for example, can be transferred from the unloading apparatus 220 in the conveying direction T to the conveyor line and therefore leaves the region 30 of the fitting system in the conveying direction.

Then, in a fifth step, as can be seen from FIG. 5f, first of all the unloading apparatus 220 is moved in the vertical direction H2 into its upper position, so that the lower holding region 280 of the unloading apparatus 220 is aligned horizontally with the conveyor line of the fitting system. Then, as can be seen from FIG. 5g, the second substrate L2 is transferred from the lower holding region 280 of the unloading apparatus 220 to the substrate carrier 130 and is moved by the latter in the direction B13 into the first fitting area 20. There, the second substrate L2 previously partly fitted in the second fitting area 40 can be fitted completely with further different components.

Therefore, according to an embodiment of the invention, it is possible to fit all the components provided at the feed modules of the individual fitting areas 20 and 40 to a substrate since, according to the further way of performing the method according to the invention, each substrate L1, L2 can pass through each fitting area 20, 40 before it leaves the fitting system again.

Thus, with a given number of feed modules for components at the individual fitting areas 20, 40, more different components to be fitted to the same substrate can be made available in a single fitting apparatus.

However, according to the further embodiment of the invention, as was already the case in accordance with the first preferred embodiment, it is also possible for already fitted substrates or substrates to be fitted in a fitting system placed downstream in the conveying direction T to be moved through the fitting system according to the further embodiment of the invention without fitting said substrates. To this end, the unloading apparatus 220 in the case of substrate carriers 130 and 110 located in the respective fitting areas 20 and 40 is moved upstream, counter to the conveying direction T, until transfer of substrates from the input station 310 to the unloading apparatus 220 is possible. After the substrate has been transferred, the unloading apparatus 220 is moved into its initial position again in the region 30 close to the edge region of the fitting system, as viewed in the conveying direction T, and from there the substrate to be moved through is transferred to the conveyor line.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A fitting system for fitting substrates with components, the substrates being fed on a substantially linear conveyor line, along which the substrates are moved substantially horizontally in a conveying direction, comprising:
at least one feed device for feeding components; and
at least one fitting area including a handling apparatus for fitting the components fed into the substrates being arranged at the side of the conveyor line, the substrates being moved between the conveyor line and the fitting area by a loading apparatus, wherein the loading apparatus includes at least two holding regions arranged one above another to hold and discharge substrates, wherein the loading apparatus includes a vertical drive, by which the holding regions are movable into positions aligned in the horizontal direction with at least one of the conveyor line and the fitting areas, and wherein positions of the substrates are transferable between the holding regions of the loading apparatus and the conveyor line.

2. The fitting system as claimed in claim 1, wherein the conveyor line includes a fitting line and a bypass line as two conveying regions lying one above another for the substrates.

3. The fitting system as claimed in claim 1, wherein the conveyor line is of a single-story design and includes a fitting line along which substrates are movable, the conveyor line including an input station.

4. The fitting system as claimed in claim 1, wherein the conveyor line is interrupted by the loading apparatus, and wherein the loading apparatus is movable along the conveying direction in the region of the interruption.

5. The fitting system as claimed in claim 1, wherein the loading apparatus is mounted above the conveyor line.

6. The fitting system as claimed in claim 1, further comprising:
at least one pair of substrate carriers including two substrate carriers, wherein one substrate carrier is assigned to the fitting areas on one of the two sides along the conveyor line and is moveable between the conveyor line and the fitting area associated with it in a movement region in a direction of movement of the pair of substrate carriers, and wherein the fitting areas of a pair of substrate carriers are arranged at a distance from each other with respect to the conveyor line in the direction of movement of the pair of substrate carriers.

7. The fitting system as claimed in claim 6, wherein the regions of movement of the substrate carriers of each pair of substrate carriers overlap in the region of the conveyor line.

8. The fitting system as claimed in claim 6, wherein a first pair of substrate carriers and a second pair of substrate carriers are arranged one behind another in the conveying direction.

9. The fitting system as claimed in claim 6, further comprising:
a second conveyor line, adapted to run parallel to the conveyor line and arranged directly beside the conveyor line;
a second loading apparatus analogous to the loading apparatus arranged along the second conveyor line, wherein the substrates are conveyable in the conveying direction to and from the substrate carriers on one of the two sides of the conveyor line by the second loading apparatus and wherein the substrates are conveyable in the conveying direction to and from the substrate carriers on the other of the two sides of the conveyor line by the loading apparatus.

10. A method of fitting substrates, comprising:
moving the substrates to be fitted along a conveyor line in a conveying direction to fitting areas, wherein the substrates are conveyable by at least one loading apparatus including at least one upper holding region and a lower holding region arranged underneath the at least one holding region, to at least one of hold and discharge substrates, at least one of between a part of the conveyor line arranged upstream and the fitting area and, by use of the same loading apparatus, to be conveyed past the fitting area to a part of the conveyor line arranged downstream.

11. The method as claimed in claim 10, wherein at least one of the upper holding region and the lower holding region of the of the loading apparatus is used to at least one of hold and discharge a substrate.

12. The method as claimed in claim 10, wherein a conveyor line, interrupted by the loading apparatus, is moveable within the region of the interruption, in and counter to the conveying direction, and wherein a substrate arranged at least one of upstream of the interruption in the fitting line and in the bypass line of the conveyor line, is transferred to at least one of the upper and lower holding region of the loading apparatus, and wherein the substrate is transferred to at least one of a fitting area and, downstream of the interruption, to at least one of the fitting line and to the bypass line.

13. The fitting system as claimed in claim 2, wherein the conveyor line is interrupted by the loading apparatus, and wherein the loading apparatus is movable along the conveying direction in the region of the interruption.

14. The fitting system as claimed in claim 3, wherein the conveyor line is interrupted by the loading apparatus, and wherein the loading apparatus is movable along the conveying direction in the region of the interruption.

15. The fitting system as claimed in claim 7, wherein a first pair of substrate carriers and a second pair of substrate carriers are arranged one behind another in the conveying direction.

16. The method as claimed in claim 11, wherein a conveyor line, interrupted by the loading apparatus, is moveable within the region of the interruption, in and counter to the conveying direction, and wherein a substrate arranged at least one of upstream of the interruption in the fitting line and in the bypass line of the conveyor line, is transferred to at least one of the upper and lower holding region of the loading apparatus, and wherein the substrate is transferred to at least one of a fitting area and, downstream of the interruption, to at least one of the fitting line and to the bypass line.
